(19) United States
(12) Patent Application Publication
(10) Pub. No.: US 2023/0110096 A1
(43) Pub. Date: Apr. 13, 2023

(54) PLASMA PROCESSING APPARATUS

(71) Applicant: HITACHI HIGH-TECH CORPORATION, Minato-ku Tokyo (JP)

(72) Inventors: Anil PANDEY, TOKYO (JP); Yoshito KAMAJI, TOKYO (JP); Masahiro SUMIYA, TOKYO (JP)

(21) Appl. No.: 17/974,727

(22) Filed: Oct. 27, 2022

Related U.S. Application Data
(63) Continuation of application No. 16/494,437, filed on Sep. 16, 2019, now abandoned.

(51) Int. Cl. H01J 37/32

(52) U.S. Cl. CPC H01J 37/32513; H01J 37/32238; H01J 37/3244; H01J 37/32834; H01J 37/32862; H01J 2237/334

(57) ABSTRACT

To reduce the damage caused due to the degradation of sealing material without complicating the structure of the vacuum sealing material of the vacuum container and to perform cleaning without affecting the lifetime of the sealing material in a plasma processing apparatus, this invention provides a plasma processing apparatus in which a window portion and a processing chamber are coupled to each other with an elastomeric sealing material sandwiched therebetween, and a sealing material is arranged at a position where a ratio of a distance from the inner wall surface of a processing chamber in an interstice portion to the sealing material with respect to the interstice between the window portion and the processing chamber having the sealing material sandwiched there between is 3 or more, in a vacuum state with the air exhausted from the processing chamber by the vacuum exhaust unit.

### TECHNICAL FIELD

This invention is related to a plasma processing apparatus and more particularly to a plasma processing apparatus configured to reduce parts damage during plasma cleaning mainly using fluorine.

### BACKGROUND ART

During semiconductor device manufacturing, there is generally a so-called plasma etching process in which a target film layer under a mask layer of photoresist and the like, winch is previously formed on the upper surface of a substrate-shaped sample such as a semiconductor wafer, arranged within a processing chamber in a vacuum container is etched along the mask layer using the plasma generated within the chamber. In such a plasma etching process, a sample substrate (wafer) is mounted on a sample table within the processing chamber and exposed to a plasma, to selectively remove a specific film stack on the wafer and to form a fine circuit pattern on the wafer.

During such plasma etching process, the gas introduced for plasma generation and the reaction byproducts generated during the removal of the film stack from the surface of the sample substrate by etching adsorb to the wall surface of the processing chamber and get deposited. The deposition of reaction byproducts on the wall surface of processing chamber cause drifts in the state of plasma generated within the processing chamber (for example, a distribution of plasma density within the processing chamber) and accordingly changes the conditions of the plasma etching (for example, distribution of the etching rate on the sample substrate surface), which causes time-dependent drifts (variations in the processed shape on the sample substrate surface) in the sequential etching processing of the surfaces of the sample substrates.

Therefore, in order to suppress the drifts in the processed shape of the sample substrate due to the change of the conditions within the processing chamber caused by the deposition of the reaction byproducts, the reaction byproducts deposited within the processing chamber are removed by plasma cleaning.

Further, it is well known that a vacuum sealing material (such as O-ring and the like; hereinafter simply referred to as a sealing material) of fluororubber and the like installed in the processing chamber is degraded and damaged by the plasma generated inside the processing chamber. In addition, since the sealing material is degraded and damaged, particle generation and vacuum leak can occur which may force unscheduled apparatus maintenance.

In order to suppress the degradation and the damage of the sealing material caused by plasma processing, for example, Japanese Unexamined Patent Application Publication No. 2006-5008 (Patent Literature 1) describes a configuration to reduce the amount of penetration of plasma or radical species into the seal member by providing a concave and convex portion in the inward side from the sealing material so as not to make the plasma come in direct contact with the sealing material.

Further, Japanese Unexamined Patent Application Publication No. 2006-194303 (Patent Literature 2) discloses a configuration that prevents the degradation of elastomeric sealing material by providing a labyrinth seal having a concave and convex portion on its surface in the inward side from an elastomeric sealing material as the main seal to irregularly reflect the plasma in this labyrinth portion and attenuate the plasma.

### PATENT LITERATURE

[Patent literature 1] Japanese Unexamined Patent Application Publication No. 2006-5008
[Patent Literature 2] Japanese Unexamined Patent Application Publication No. 2006-194303

### SUMMARY OF INVENTION

### Technical Problem

However, the above-mentioned conventional art, has such problems that the structure of the vacuum seal portion of the vacuum container becomes complicated because of the concave and convex portion in the inward side from the sealing material and the labyrinth structure with the concave and convex formed on the surface in the inward side from the sealing material, accordingly the apparatus itself gets more expensive, and it takes more time for maintenance of the apparatus.

Therefore, the present invention provides a plasma processing apparatus capable of reducing the damage caused by the degradation of the sealing material without using a complicated structure of the vacuum seal portion of the vacuum container and performing cleaning without affecting the lifetime of the sealing material.

### Solution to Problem

In order to solve the above-mentioned problems, this invention includes: a processing chamber, a vacuum exhaust unit which evacuates the processing chamber, a gas supply unit which supplies gas into the processing chamber, a sample table on which target sample to be processed is mounted, a window portion which forms a ceiling surface of the processing chamber above the sample table; a microwave power supply unit including a waveguide which supplies microwave power into the processing chamber via the waveguide through the window portion and solenoid coils which are disposed surrounding around the processing chamber, the microwave power and the magnetic field from the solenoid coils generating a plasma inside the processing chamber by Electron Cyclotron Resonance (ECR), in which the window portion and the processing chamber are coupled to each other with an elastomeric sealing material sandwiched therebetween, and the sealing material is arranged at a position where the ratio of the distance from an inner wall surface of the processing chamber in an interstice portion to the sealing material, with respect to the interstice between the window portion and the processing chamber having the sealing material sandwiched there between, is 3 or more, while exhausting the processing chamber by a vacuum exhaust unit to set an internal pressure of the processing chamber at 10 to 20 Pa. and performing a cleaning process in order to remove a film or deposition attached to the inside of the processing chamber using the plasma generated by ECR using the microwave power which is supplied from the microwave power supply unit into the processing chamber to generate plasma and the magnetic field which is supplied from the solenoid coils, in which state damage to the sealing material caused by radicals during the cleaning process generating the plasma which passes through the interstice between the window portion and the processing chamber and arrives at the sealing material is not a decisive factor of lifetime of the sealing material.

Further, in order to solve the above-mentioned problems, the invention includes a processing chamber, a vacuum exhaust unit which evacuates the processing chamber to vacuum, a gas supply unit which supplies a gas into the processing chamber, a sample table which mounts a target sample arranged within the processing chamber, a window portion which is formed by dielectric material to form a ceiling surface of the processing chamber above the sample table, and a microwave power supply unit including a waveguide which supplies microwave power into the processing chamber via the waveguide through the window portion and solenoid coils which are disposed surrounding around the processing chamber, the microwave power and the magnetic field from the solenoid coils generating a plasma inside the processing chamber by Electron Cyclotron Resonance (ECR), being provided with a function of performing the etching process of etching the sample mounted on the sample table using the plasma while supplying a first gas from the gas supply unit into the processing chamber and, in a state where the etched sample is taken out from the processing chamber, the cleaning processing of generating the plasma within the processing chamber while supplying a second gas from the gas supply unit into the processing chamber to eliminate the products attached to the inside of the processing chamber after the etching processing, in which the window portion and the processing chamber are coupled to each other with an elastomeric sealing material sandwiched therebetween, and the sealing material is arranged at a position where a ratio of a distance from an inner wall surface of the processing chamber in an interstice portion to the sealing material with respect to the interstice between the window portion and the processing chamber having the sealing material sandwiched there between is 3 or more, while the second gas including nitrogen trifluoride (NF₃) is supplied from the gas supply unit into the processing chamber and vacuun-exhausting from the processing chamber by the vacuum exhaust unit to set an internal pressure of the processing chamber at 10 to 20 Pa, and performing the cleaning process using the plasma generated by the microwave power which is supplied from the microwave power supply unit and the magnetic field from the solenoid coils into the processing chamber, in which state damage to the sealing material caused by radicals during the cleaning process generating the plasma which passes through the interstice between the window portion and the processing chamber and arrives at the sealing material is not a decisive factor of lifetime of the sealing material.

### Advantageous Effects of Invention

According to the present invention, it is possible to provide a plasma processing apparatus that can perform the cleaning in a damage-reduced state while suppressing the degradation of the sealing material without using a complicated the structure of the vacuum seal portion of the vacuum container.

Further, from the present invention, it is possible to provide a plasma processing apparatus with suitable vacuum seal structure which can reduce the damage due to the degradation of the sealing material caused by plasma processing and also extend the maintenance cycle without shortening the lifetime of the vacuum material.

### BRIEF DESCRIPTION OF DRAWINGS

FIG. 1 is a schematic block diagram showing one example of a schematic structure of a plasma processing apparatus according to the embodiment.

FIG. 2 is a cross-sectional view of a processing chamber wall surface and a dielectric window of the plasma processing apparatus shown in FIG. 1.

FIG. 3A is a view showing the cross-section of the sealing material peripheral portion sandwiched between the processing chamber wall surface and the dielectric window shown in FIG. 2, when the inside of the processing chamber is in a state of atmospheric pressure.

FIG. 3B is a view showing the cross-section of the sealing material peripheral portion sandwiched between the processing chamber wall surface and the dielectric window shown in FIG. 2, when the inside of the chamber is in a vacuum state.

FIG. 4 is a graph showing a relation between an index (aspect ratio) ratio indicating the structure of the space leading from the plasma generation area to the sealing material, and the damage amount of the sealing material.

FIG. 5 is a graph showing a relation between internal pressure of the processing chamber during plasma generation mainly using fluorine and the fluorine radical amount in the plasma area (or a cleaning rate of the reaction byproducts deposited on the inner wall surface of the processing chamber) and the fluorine radical amount (a damage rate of the sealing material) in the vicinity of the sealing material dependent on the pressure.

FIG. 6 is a graph showing relationship between sputtering rate and pressure within the processing chamber.

### DESCRIPTION OF EMBODIMENTS

Generally, in a plasma processing apparatus, it is difficult to uniquely determine the distance from any point in the processing chamber to the vacuum sealing material and the structure of the space leading from the plasma generation area to the sealing material to sufficiently suppress the damage of the sealing material, under every plasma processing condition.

This invention enables the plasma processing apparatus to reduce the damage caused by the degradation of the vacuum sealing material for repeated and stable plasma cleaning, without any need to lengthen or complicate the structure leading the seal portion, based on the founding that the amount of the radicals entering the space (interstice) far from the plasma area depends on the plasma generation conditions of gas species, pressure, discharge power, and the like used for plasma generation. In other words, the degree of the damage of the sealing material arranged in the interstice between the materials changes depending on the plasma generation conditions.

Specifically, this invention relates to the plasma processing apparatus including a processing chamber where a processing gas is supplied and the plasma is formed, which is arranged within a vacuum container, a sample table with a target wafer mounted on the top surface, which is arranged in the lower portion within this processing chamber, and a sealing material chamber which is sandwiched between the two materials forming the inner wall surfaces of the processing chamber and decompressed, for hermetically separating the inside of the processing chamber where the plasma is formed from the outside in a state of atmospheric pressure. Especially, in the plasma processing using the plasma of a high dissociation degree mainly using fluorine where use condition is severe and the high concentration radicals, the pressure within the chamber under the processing is set at 10 Pa to 20 Pa.

Further, the invention is characterized in that a space formed between the surfaces of the two materials with the sealing material sandwiched therebetween connected with the inside of the chamber where the plasma is formed through an interstice of a predetermined size, and that a ratio of the length of the interstice with respect to the distance (interval) between the inner wall surfaces forming the interstice is 3 or more. Further, as the sealing material, a fluorine rubber material is used.

In the plasma cleaning using the fluorine gas whose use condition is severe, the plasma of high dissociation degree mainly using the fluorine gas and the high concentration radicals are used; therefore, a damage amount to the sealing material becomes large. By this invention, however, it is possible to reduce the damage due to the degradation of the sealing material caused by the plasma processing and extend the maintenance cycle of the plasma processing apparatus without shortening the lifetime of the vacuum material.

Hereinafter, an embodiment of the plasma processing apparatus according to the invention will be described using the drawings. The invention, however, is not to be interpreted as being restricted to the described contents of the embodiment shown below. Those skilled in the art easily understand that various modifications of the concrete structure are possible without departing from the spirit and scope of the invention.

### Embodiment

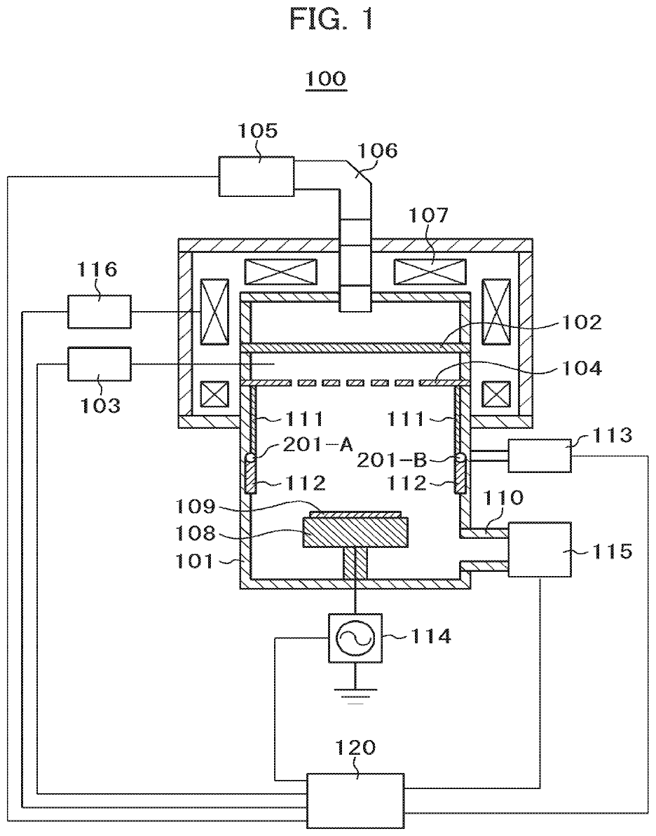

Using FIGS. 1 to 6, the embodiment of the invention will be described.

FIG. 1 is a schematic cross-sectional view showing one example of a dry etching device as the plasma processing apparatus according to the embodiment; an electron cyclotron resonance (Electron Cyclotron Resonance: ECR) type etching device, using a microwave and magnetic field as a plasma generation means. Hereinafter, the electron cyclotron resonance is described as ECR.

A dry etching device 100 shown in FIG. 1 includes a microwave power source 105, a microwave waveguide 106, and solenoid coils 107 provided in the outer periphery and on the top of the processing chamber 101, as a mechanism for generating the plasma. A dielectric window 102 and a disc-shaped shower plate 104 with a plurality of fine holes for supplying an etching gas are arranged in the upper portion of the processing chamber 101.

The inside of the processing chamber 101 is decompressed by evacuating the air through a vacuum exhaust tube 110 by a vacuum pump 115. To maintain the decompressed pressure within the processing chamber 101, the dielectric window 102 in the upper portion of the processing chamber 101 and the space between the dielectric window 102 and the processing chamber 101 is sealed by the sealing material (not illustrated).

Inside the processing chamber 101, a substrate electrode 108 for mounting a wafer 109 as a sample is provided and the electrode 108 is coupled to a high frequency power source 114 for supplying a high frequency power from the outside of the processing chamber 101. An electrostatic chuck (not illustrated) is configured for electrostatically attracting the wafer 109, on the to the surface of the substrate electrode 108 and although a cooling mechanism for cooling the wafer 109 electrostatically attracted by the electrostatic chuck is provided, the above is not displayed for the sake of making the drawing simple.

Further, the inside of the processing chamber 101 is assembled with a plurality of parts such as an inner tube 111, earth 112, quartz windows 201-A and 201-B, and the like. Each space between the quartz windows 201-A and 201-B and the processing chamber 101 is sealed by the sealing material not illustrated in FIG. 1, to keep the air-tightness inside the processing chamber 101. A spectroscopic measurement unit 113 for monitoring the state of the plasma generated within the processing chamber 101 is provided outside of the quartz window 201-B. The spectroscopic measurement unit 113 is coupled to a control unit 120, to send the signals obtained by monitoring the state of the plasma inside of the processing chamber 101 to the control unit 120.

The dry etching apparatus 100 having the above-mentioned configuration the control unit 120 controls the microwave power source 105, a gas supply device 103, the high frequency power source 114, the vacuum pump 115, and the power supply source 116 and generates a plasma inside of the processing chamber 101, by a predetermined procedure, performing etching process on the wafer 109 mounted on the substrate electrode 108.

In the etching process of the wafer 109, first, the control unit 120 operates the vacuum pump 115 and starts the decompression and evacuation inside the processing chamber 101. After the inside of the processing chamber 101 is evacuated to a predetermined pressure, the wafer 109 as a semiconductor substrate to be processed is mounted on the substrate electrode 108, that is a mounting table of a sample, by a transport device (not illustrated) such as a robot arm.

Next, the gas supply device 103 controlled by the control unit 120 supplies the etching gas to the space between the dielectric window 102 and the shower plate 104 in the upper portion of the processing chamber 101, the gas is introduced into the processing chamber 101 through a plurality of fine holes formed in the shower plate 104, and the inside of the chamber is set at a predetermined pressure.

In this state, the control unit 120 controls the microwave power source 105 to generate microwave. The microwave generated by the microwave power source 105 is introduced to the upper portion of the processing chamber 101 through the microwave waveguide 106.

On the other hand, the control unit 120 controls the power supply source 116 to generate a strong magnetic field by the solenoid coils 107, such that it satisfies the ECR condition for the microwave introduced to the upper portion of the processing chamber 101 through the microwave waveguide 106, in the space including the upper portion of the processing chamber 101.

By supplying the microwave to the area where the above magnetic field is formed, energy is provided to the electrons through the ECR. The electrons ionize the etching gas introduced into the processing chamber 101, hence generate a high density plasma.

In a state with the plasma generated inside the processing chamber 101, when the control unit 120 controls the high frequency power source 114 to apply a high frequency electric power to the substrate electrode 108, a negative potential called self bias occurs on the surface of the wafer 109. The negative potential draws ions from the plasma to the wafer 109, so that the etching processing proceeds on the surface of the wafer 109.

After the etching for a predetermined time on the surface of the wafer 109, or when the spectroscopic measurement unit 113 detects the end point of the etching process, the control unit 120 controls the gas supply device 103, the microwave power source 105, the high frequency power source 114, and the power source 116 of the solenoid coils 107 respectively, to finish the etching processing of the wafer 109. By performing the etching process on the surface of the wafer 109, a portion of the surface of the wafer 109 is removed. Although a part of the removed material is discharged outside of the processing chamber 101 by the vacuum pump through the vacuum exhaust tube 110, the others stick to the inner wall surface of the processing chamber 101 as a film or a deposition.

After completion of the etching processing, the wafer 109 is raised up from the substrate electrode 108, using a carrying device such as a robot arm not illustrated and carried out from the processing chamber 101.

Next, the control unit 120 switches the types of the gases to be supplied from the gas supply device 103 to the inside of the processing chamber 101, and supplies a cleaning gas from the gas supply device 103 to the inside of the processing chamber 101 where the wafer 109 has been carried out. The type of the cleaning gas has to be changed depending on the type of the film and the deposition attached to the inner wall surface of the processing chamber 101; for example, a gas with argon (Ar) added to nitrogen trifluoride (NF₃) is used. By supplying the microwave generated by the microwave power source 105 into the magnetic field formed by the solenoid coils 107, the plasma of the cleaning gas is generated inside the processing chamber 101.

By generating the cleaning gas plasma inside the processing chamber 101 for a predetermined time, the film and the deposition attached to the inside of the processing chamber 101 caused by the etching process is removed. After cleaning the inside of the processing chamber 101 for a predetermined time, the control unit 120 controls the gas supply device 103 to stop the supply of the cleaning gas, the solenoid coils 107 to stop the formation of the magnetic field, and the microwave power source 105 to stop the generation of the microwave respectively, to finish the cleaning of the inside of the processing chamber 101.

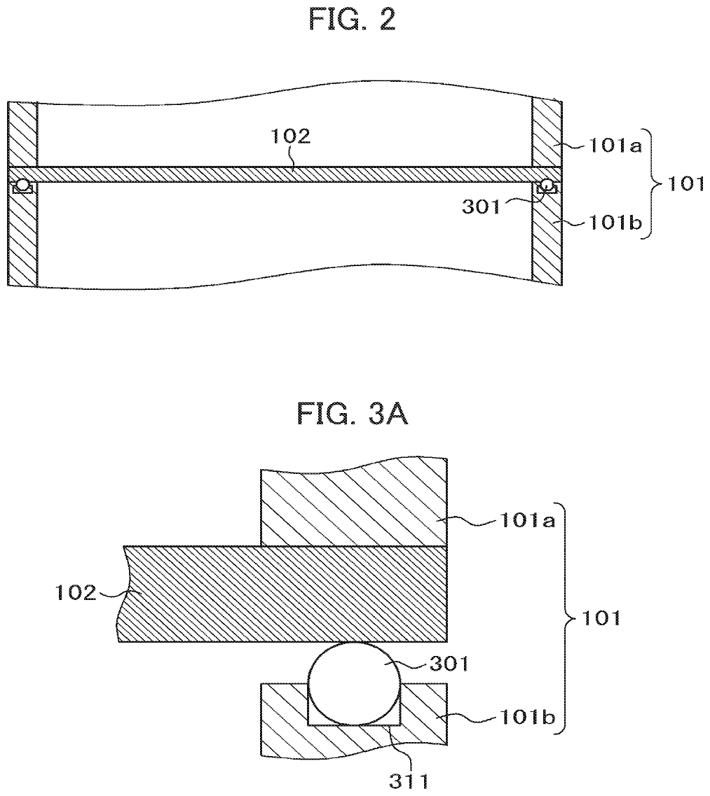

FIG. 2 is a cross-sectional view showing a relation between the processing chamber 101 and the dielectric window 102 of the dry etching device 100 as the plasma processing apparatus according to the first embodiment of the invention. The processing chamber 101 is formed by the chamber upper portion 101a and the chamber lower portion 101b with the dielectric window 102 intervening therebetween. The space between the chamber lower portion 101b and the dielectric window 102 is vacuum-sealed by an O-ring as the sealing material 301. The O-ring as the sealing material 301 is formed by an elastomeric material such as vinylidene fluoride-based fluorine-containing rubber.

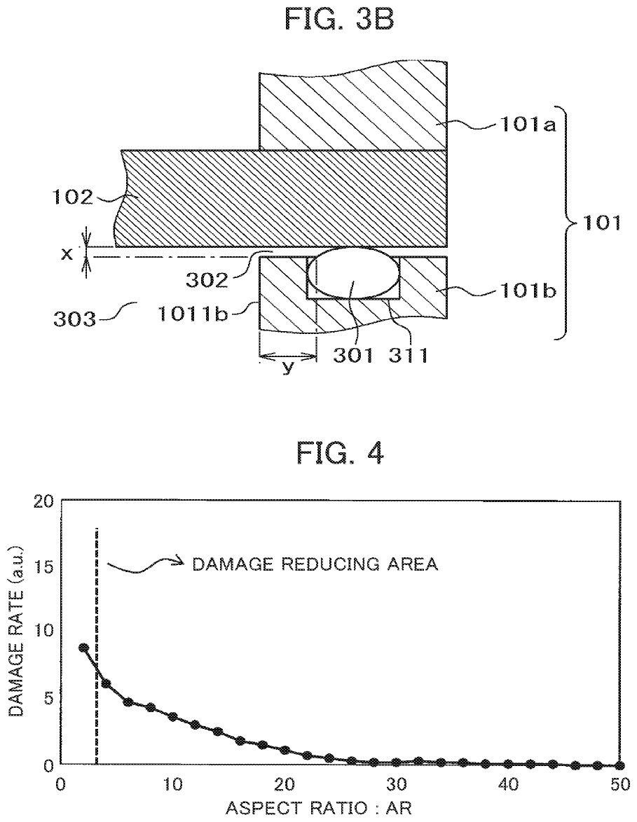

FIGS. 3A and 3B are enlarged views of the periphery of the sealing material arranged between the chamber lower portion 101b and the dielectric window 102 shown in FIG. 2. FIG. 3A shows the state where the inside of the processing chamber 101 is in the atmospheric pressure. The O-ring as the sealing material 301 is embedded in a groove portion 311 formed in the chamber lower portion 101b and sandwiched between the chamber lower portion 101b and the dielectric window 102.

In this structure, when the inside of the processing chamber 101 is evacuated and decompressed, the O-ring as the sealing material 301 is crushed and deformed between the chamber lower portion 101b and the dielectric window 102, as illustrated in FIG. 3B, to generate a fine interstice 302 between the chamber lower portion 101b and the dielectric window 102. Here, in FIG. 3B, a reference numeral 303 indicates the area where the plasma occurs within the processing chamber 101.

In a state with the inside of the processing chamber 101 evacuated and decompressed as illustrated in FIG. 3B, a distance from the inlet portion of the interstice 302 on the inner wall surface 1011b of the chamber lower portion 101b to the portion of the crushed and deformed O-ring as the sealing material 301 bulging out from the groove portion 311 is defined as y. A distance in the fine interstice 302 generated between the chamber lower portion 101b and the dielectric window 102 is defined as x.

The aspect ratio (Aspect Ratio; hereinafter, referred to as AR) of the distance y from the end portion of the interstice 302 to the sealing material 301 and the distance x between the materials is defined as the following expression . . . (Expression 1).

AR=y/x (Expression 1)

FIG. 4 is a graph showing a relation between AR and the rate at which damage to a sealing material advances while using NF₃ plasma generated based on the condition shown in the table 1. Specifically, as shown in the table 1, the flow rate of the argon gas (Ar) supplied from the gas supply device 103 to the processing chamber 101 is 50 ml/min and the flow rate of the NF₃ is 750 ml/min, with the internal pressure of the processing chamber 101 set at 12 Pa, a microwave power of 1000 W microwave power was applied to generate plasma inside the processing chamber 101.

TABLE 1 [symbol]
1

| | |
|---|---|
| Gas Flow Rate | Discharge |

| | | | |
|---|---|---|---|
| Ar | NF₃ | Pressure | Power |

| | | | |
|---|---|---|---|
| S. N | (ml/min) | Pa | W |

| | | | | |
|---|---|---|---|---|
| 1 | 50 | 750 | 12 | 1000 |

As the result of performing the plasma cleaning by projecting microwave power into the processing chamber 101 under the above-mentioned condition to generate the plasma of comparatively higher density, the damage rate of the sealing material 301 depends on the AR up to about the AR value of 25 and accordingly as the value of the AR becomes larger, the damage rate becomes less, as shown in FIG. 4.

This is because in the interstice 302 between the chamber lower portion 101b and the dielectric window 102 with a distance from each other x, the amount of radicals entering from the plasma generation area 303 and moving along the direction of the surface of the material forming the interstice 302 to the position of the distance y, is considered to be reduced according to the length of the moving distance y.

By fixing the AR, the ratio of the distance x between the materials forming the interstice 302 and the distance y from the inlet of the interstice 302 on the side of the plasma generation area 303 to the sealing material 301, at 25 and more, according to FIG. 4, the damage of the sealing material 301 can be almost zero. In FIG. 4, when the value of the AR is in the area at a right side from a dotted line 401, in short, more than 3, the damage of the sealing material 301 can be reduced in a practical range without raising the swap frequency of the sealing material 301.

In other words, by setting the sealing material 301 at the position of the AR 3 or more, in a state of the plasma generated within the processing chamber 101, the radicals during the plasma passing through the fine interstice 302 with the distance x generated between the upper surface of the chamber lower portion 101b and the dielectric window 102 and arriving at the sealing material 301 can be avoided from damaging the sealing material 301 seriously, to an extent which does not become the determining factor of the lifetime of the sealing material 301.

The damage of the sealing material 301 that does not become a factor that determines the lifetime of the seal vanes depending on the generation conditions of plasma within the processing chamber 101 and the conditions of processing the film layer on the wafer 109. So, in order to suppress the damage of the sealing material 301, it is necessary to select the AR of the interstice 302 in consideration of the conditions of the plasma.

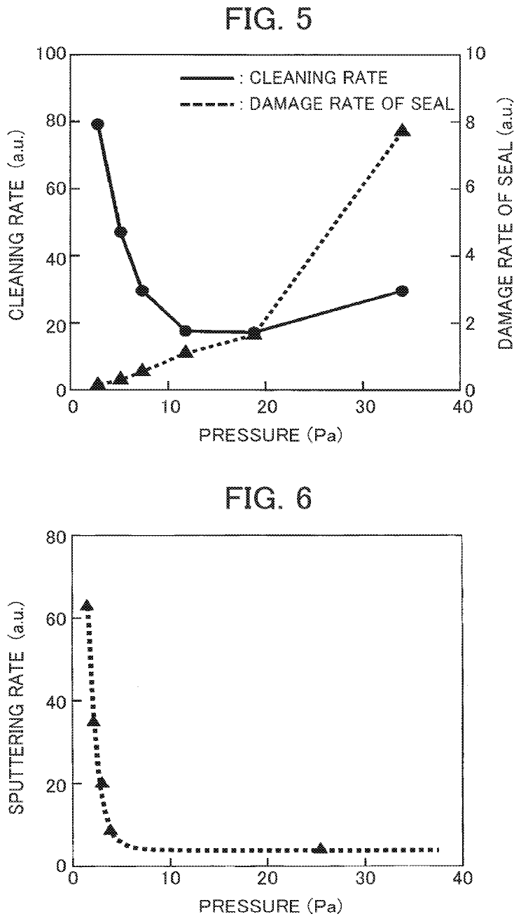

FIG. 5 is a graph which shows the relationship between the pressure inside processing chamber 101 at the time of plasma generation and the cleaning rate (solid line: left axis) as well as the damage rate of sealing material (dotted line: right axis) when the chamber 101 is configured in such a way that the gap 302 between lower portion 101b of the processing chamber and the dielectric window 102 and the seal member 301 is at AR of 3. Here, as the plasma cleaning gas, NF₃ is used.

In this figure, the amount of the damage or wear of the sealing material 301 is indicated by the dashed line and the rate of etching and cleaning the film or deposition formed on the material surfaces forming the interstice 302 in the end portion as the inlet of the interstice 302 (cleaning rate) is indicated by the solid line. As shown in the above figure, in a range where the pressure within the processing chamber 101 is relatively lower (for example, 20 Pa and less) at the plasma processing time, it is found that although the cleaning rate (axis at the left side) is higher, the damage rate (axis at the right side) of the sealing material 301 is lower.

According to the plasma cleaning, the film or the deposition attached to the inner wall surface of the processing chamber 101 is removed by the etching processing, while in the portion of the inner wall surface without the film or the deposition or the portion with the film or the deposition eliminated, the inner wall surface of the processing chamber 101 is subjected to the sputtering and may be damaged by relatively higher energy ions of the plasma.

FIG. 6 is a graph showing a change of the sputtering rate on the inner wall surface of the processing chamber by the plasma formed in the processing chamber, according to the change of the pressure value of the processing chamber. As shown in this figure, it is found that the sputtering rate on the surface of the material forming the inner wall of the processing chamber 101 becomes rapidly higher in the range of the pressure value lower than 10 Pa than in the range of the pressure value higher than 10 Pa.

Therefore, when the pressure within the processing chamber 101 is lower than 10 Pa, the amount of the wear or damage of the material facing the plasma in the processing chamber 101 becomes larger. As a result the a frequency of temporarily stopping the operation of processing the wafer 109 in the processing chamber 101, opening the vacuum container into atmospheric pressure, and exchanging the worn out or damaged parts increase. Hence deteriorating the operation yield of the apparatus.

From the result of the above examination, the inventor et al. have found that the AR in the fine interstice 302 generated between the upper surface of the chamber lower portion 101b and the dielectric window 102 in a state with the sealing material 301 sandwiched there between should be 3 or more than 3 and that the pressure of generating the plasma within the processing chamber 101 should be preferably in a range of 10 Pa to 20 Pa, in order to achieve the purpose of fully enhancing the cleaning performance to eliminate the film attached or deposited to the inner wall surface of the processing chamber 101 by supplying the cleaning gas of NF₃ and the like into the processing chamber 101 and forming the plasma, and reducing the wear or the damage of the sealing material 301 affected by the plasma to a degree not affecting the lifetime of the sealing material 301, hence to enhance the yield of the processing of the wafer 109 within the processing chamber 101 and the efficiency of the operation of the plasma processing apparatus.

In the embodiment, after performing the process of etching the target film layer formed on the surface of the wafer 109, or in the process of cleaning the inner wall surface of the processing chamber 101 before staring the above process after the wafer 109 is carried into the processing chamber 101, the control unit 120 controls the gas supply device 103 and the vacuum pump 115, to keep the pressure within the processing chamber 101 at a predetermined value within the range of 10 to 20 Pa. and to supply the NF₃ gas into the processing chamber 101 to form the cleaning plasma.

Although the embodiment has been described in the case of using the gas including NF₃ as the plasma cleaning gas, the plasma cleaning gas is not restricted to this but depending on the plasma etched material, a gas including chlorine (Cl₂) and a gas including oxygen (O₂) may be applied to generate the plasma for the plasma cleaning.

Even when using the above plasma cleaning gas, similarly to the case of the above-mentioned embodiment, by forming the AR in the fine interstice 302 generated between the upper surface of the chamber lower portion 101b and the dielectric window 102 with the sealing material 301 sandwiched there between to be 3 or more than 3 and keeping the pressure within the processing chamber 101 at a predetermined value within the range of 10 to 20 Pa, the same effect as described in the above mentioned embodiment can be obtained.

In the above-mentioned example, although the example of the fine interstice 302 generated between the upper surface of the chamber lower portion 101b and the dielectric window 102 with the sealing material 301 sandwiched therebetween has been described, the same can be applied to the sealing material not illustrated between the quartz windows 201-A and 201-B and the chamber lower portion 101b. Specifically, also in the portion with the sealing material attached between the quartz windows 201-A and 201-B and the chamber lower portion 101b, the AR is formed to be larger than 3, similarly to the above-mentioned embodiment, hence to reduce the exhaustion or the damage affecting the sealing material caused by the plasma generated within the processing chamber 101 to a degree of not affecting the lifetime of the sealing material.

As set forth hereinabove, the invention made by the inventor et al. has been described specifically based on the embodiment, it is needless to say that the invention is not restricted to this embodiment but various modifications without departing from the spirit can be possible. For example, the above-mentioned embodiment has been described in details for the sake of easily understanding the invention; therefore, the invention is not restricted to the structure having all the described components. Further, a part of the structure of the embodiment can be added to, deleted from, or replaced with the other known component.

### LIST OF REFERENCE SIGNS

100: dry etching device
101: processing chamber
102: dielectric window
103: gas supply device
104: shower plate
105: microwave power source
106: microwave waveguide
107: solenoid coil
108: substrate electrode
109: wafer
110: vacuum exhaust tube
111: inner tube
112: earth
113: spectroscopic measurement unit
114: high frequency power source
115: vacuum pump
116: power source
120: control unit
301: sealing material
311: groove portion

1-10. (canceled)

11. A plasma processing method for processing a target sample using plasma inside a plasma processing apparatus, the plasma processing apparatus comprising:
a processing chamber;
a vacuum exhaust unit which evacuates the processing chamber to vacuum;
a gas supply unit which supplies a gas into the processing chamber;
a sample table which mounts a target sample arranged within the processing chamber;
a window portion which is formed by dielectric material to form a ceiling surface of the processing chamber above the sample table; and
a microwave power supply unit including a waveguide which supplies microwave power into the processing chamber via the waveguide through the window portion and solenoid coils which is disposed surrounding around the processing chamber, the microwave power and the magnetic field from the solenoid coils generating a plasma inside the processing chamber by ECR,
wherein the window portion and the processing chamber are coupled to each other with an elastomeric sealing material sandwiched therebetween, and the sealing material is arranged at a position where the ratio of the distance from an inner wall surface of the processing chamber in an interstice portion to the sealing material, with respect to the interstice between the window portion and the processing chamber having the sealing material sandwiched there between, is 3 or more, and,
the plasma processing method comprising steps of:
exhausting the processing chamber by a vacuum exhaust unit to set an internal pressure of the processing chamber at 10 to 20 Pa;
performing a cleaning process in order to remove a film or deposition attached to the inside of the processing chamber using the plasma generated by ECR using the microwave power which is supplied from the microwave power supply unit into the processing chamber to generate plasma and the magnetic field which is supplied from the solenoid coils.

12. The plasma processing method according to claim 11, wherein
in performing the cleaning process, a damage to the sealing material caused by radicals during the cleaning process generating the plasma which passes through the interstice between the window portion and the processing chamber and arrives at the sealing material is not a decisive factor of lifetime of the sealing material.

13. The plasma processing method according to claim 11,
wherein the elastomeric sealing material is formed of vinylidene fluoride-based fluorine-containing rubber.

14. The plasma processing apparatus according to claim 11,
wherein the elastomeric sealing material is an O-ring.

15. The plasma processing method according to claim 14,
wherein the O-ring is embedded into a groove portion formed in the processing chamber, and the distance from the inner wall surface of the processing chamber in the interstice portion to the sealing material is a distance from the inner wall surface of the processing chamber to a portion bulging from the groove portion, of the O-ring embedded in the groove portion.

16. A plasma processing method for processing a target sample using plasma inside a plasma processing apparatus, the plasma processing apparatus comprising:
a processing chamber;
a vacuum exhaust unit which evacuates the processing chamber into vacuum;
a gas supply unit which supplies a gas into the processing chamber;
a sample table which mounts a target sample arranged within the processing chamber;
a window portion which is formed by dielectric material to form a ceiling surface of the processing chamber above the sample table; and
a microwave power supply unit including a waveguide which supplies microwave power into the processing chamber via the waveguide through the window portion and solenoid coils which is disposed surrounding around the processing chamber, the microwave power and the magnetic field from the solenoid coils generating a plasma inside the processing chamber by ECR,
wherein the window portion and the processing chamber are coupled to each other with an elastomeric sealing material sandwiched therebetween, and the sealing material is arranged at a position where a ratio of a distance from an inner wall surface of the processing chamber in an interstice portion to the sealing material with respect to the interstice between the window portion and the processing chamber having the sealing material sandwiched there between is 3 or more, and,
the plasma processing method comprising steps of:
performing etching processing of etching the sample mounted on the sample table using the plasma while supplying a first gas from the gas supply unit into the processing chamber and, in a state where the etched sample is taken out from the processing chamber, cleaning processing of generating plasma by ECR within the processing chamber while supplying a second gas including nitrogen trifluoride (NF₃) from the gas supply unit into the processing chamber to eliminate products attached to the inside of the processing chamber through the etching processing,
vacuum-exhausting from the processing chamber by the vacuum exhaust unit to set an internal pressure of the processing chamber at 10 to 20 Pa, and
performing the cleaning process using the plasma generated by the microwave power which is supplied from the microwave power supply unit and the magnetic field from the solenoid coils into the processing chamber.

17. The plasma processing method according to claim 16, wherein
in performing the cleaning process, damage to the sealing material caused by radicals during the cleaning process generating the plasma which passes through the interstice between the window portion and the processing chamber and arrives at the sealing material is not a decisive factor of lifetime of the sealing material.

18. The plasma processing method according to claim 16,
wherein the elastomeric sealing material is formed of vinylidene fluoride-based fluorine-containing rubber.

19. The plasma processing method according to claim 16,
wherein the elastomeric sealing material is an O-ring.

20. The plasma processing method according to claim 19,
wherein the O-ring is embedded into a groove portion formed in the processing chamber, and the distance from the inner wall surface of the processing chamber in the interstice portion to the sealing material is a distance from the inner wall surface of the processing chamber to a portion bulging from the groove portion, of the O-ring embedded in the groove portion.
